(19) United States
(12) Patent Application Publication
(10) Pub. No.: US 2018/0331045 A1
(43) Pub. Date: Nov. 15, 2018

(54) VARIABLE RESISTANCE VIAS AND RELATED METHODS

(71) Applicant: SEMICONDUCTOR COMPONENTS INDUSTRIES, LLC, Phoenix, AZ (US)

(72) Inventors: Eric AMEELE, Sandy, OR (US); E. William COWELL, III, Portland, OR (US)

(73) Assignee: SEMICONDUCTOR COMPONENTS INDUSTRIES, LLC, Phoenix, AZ (US)

(21) Appl. No.: 15/920,880

(22) Filed: Mar. 14, 2018

Related U.S. Application Data
(60) Provisional application No. 62/503,815, filed on May 9, 2017.

(51) Int. Cl. H01L 23/532; H01L 21/768; H01L 21/285

(52) U.S. Cl. CPC H01L 23/53266; H01L 21/28556; H01L 21/76846; H01L 21/76847

(57) ABSTRACT

Implementations of a via for a semiconductor devices may include a first tungsten layer deposited conformally within the via, and may be recessed within the via, and a second tungsten layer deposited into the recess over the first tungsten layer. A plane formed by the second tungsten layer may be substantially parallel with a plane aligned substantially perpendicularly with a longest dimension of the via viewed in cross section.

### CROSS REFERENCE TO RELATED APPLICATIONS

This document claims the benefit of the filing date of U.S. Provisional Patent Application 62/503,815, entitled “Variable Resistance Flat Top Vias and Related Methods” to Cowell et al. which was filed on May 9, 2017, the disclosure of which is hereby incorporated entirely herein by reference.

### BACKGROUND

### 1. Technical Field

Aspects of this document relate generally to electrically conductive structures, such as vias having a flat top for forming electrical connections between various devices. More specific implementations involve vias having variable resistance.

### 2. Background

Conventionally, interconnects have been incorporated within semiconductor devices to form electrical connections within the device as well as electrical connections between the device and exterior devices. Interconnects have included wire bonds, conductive routing, flip chips, and vias. Vias are used to form an electrical connection through a silicon wafer or a die.

### SUMMARY

Implementations of a via for a semiconductor devices may include a first tungsten layer deposited conformally within the via, and may be recessed within the via, and a second tungsten layer deposited into the recess over the first tungsten layer. A plane formed by the second tungsten layer may be substantially parallel with a plane aligned substantially perpendicularly with a longest dimension of the via viewed in cross section.

Implementations of vias may include one, all, or any of the following:

The second tungsten layer may be less than one-half a width of the via.

A first liner may be coupled to the first tungsten layer.

A second liner may be coupled between the second tungsten layer and the first tungsten layer.

The second liner may include either titanium nitride or tantalum nitride.

The material of the second liner may include a higher effective resistance than tungsten.

The first tungsten layer may be directly coupled to the second tungsten layer.

Implementations of a via for a semiconductor device may include a first liner coupled to a first portion of a surface of the via, a first layer coupled to the first liner, a second liner coupled to a second portion of the surface of the via and to the first layer, and a second layer coupled to the second liner. A material of the second liner may have a different effective resistance than a material of the second layer.

Implementations of vias may include one, all, or any of the following:

The first layer may be tungsten.

The second layer may be tungsten.

The second layer may be deposited into a recess of the first layer.

The second layer may be less than one half a width of the via.

A plane formed by the second tungsten layer may be substantially parallel with a plane aligned substantially perpendicularly with a longest dimension of the via.

Implementations of a method for forming a via may include depositing a first liner on a surface of a via, depositing a first tungsten layer over the first liner within the via, polishing the first tungsten layer, etching a portion of the first tungsten layer to form a recess in the via, depositing a second liner over the first tungsten layer into the recess, depositing a second tungsten layer over the second liner into the recess, and polishing the second tungsten layer.

Implementations of methods for forming a via may include one, all, or any of the following:

The second tungsten layer may be deposited using chemical vapor deposition.

A plane formed by the second tungsten layer may be substantially parallel with a plane aligned substantially perpendicularly with a longest dimension of the via.

The material of the second liner may be configured to adjust the effective resistance of the via.

The second liner may include either titanium nitride or tantalum nitride.

The material of the second liner may include a higher effective resistance than tungsten.

The second tungsten layer may not include a seam therein.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross-section side view of a first implementation of a via;

FIG. 2 is a cross-section side view of three vias with a structure similar to the via of FIG. 1;

FIG. 3 is a cross-section side view of a second implementation of a via; and

FIGS. 4A-4D are cross-section side views of a method for forming the via of FIG. 3.

### DESCRIPTION

This disclosure, its aspects and implementations, are not limited to the specific components, assembly procedures or method elements disclosed herein. Many additional components, assembly procedures and/or method elements known in the art consistent with the intended vias will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such vias, and implementing components and methods, consistent with the intended operation and methods.

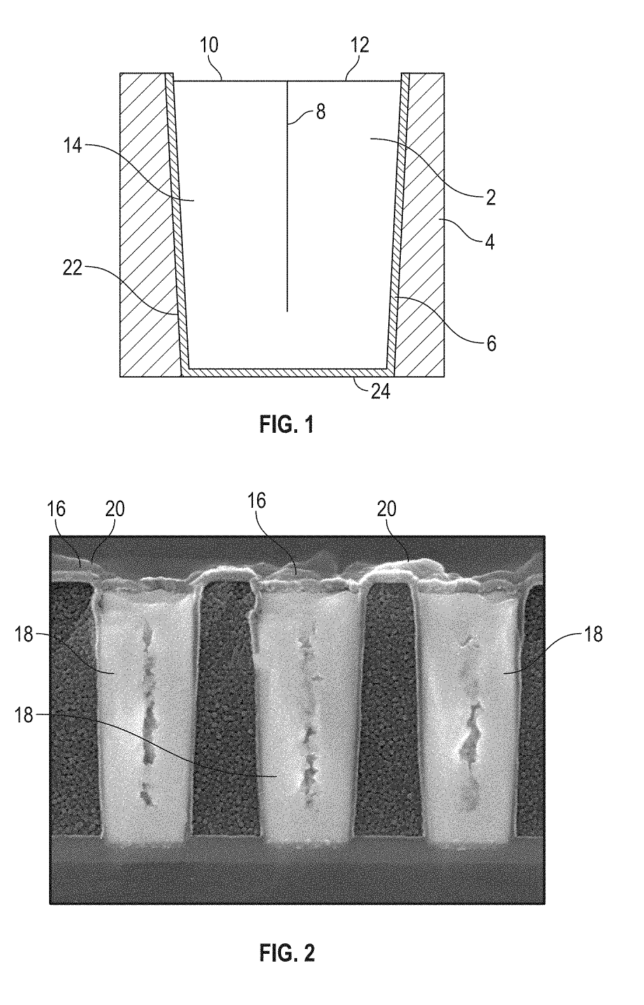

Referring to FIG. 1, a cross-section side view of a first implementation of a via is illustrated. The via 2 may extend through a layer 4 of a semiconductor device. The layer 4 of the semiconductor device may include, by non-limiting example, an inter-layer dielectric material. The via may include a conductive layer. The conductive layer may be any metal or metal alloy, and in particular implementations, includes tungsten. While this application primarily refers to the via including a tungsten layer 14, it is understood that rather than tungsten, alternative electrically conductive materials could be used in place of tungsten as used throughout this disclosure. In various implementations, the via 2 may include a liner material 6 coupled to the tungsten layer 14 and to the surface 22 between the layer 4 of the semiconductor device and the via 2. In various implementations, the tungsten layer 14 may be deposited conformally within the via, meaning that the tungsten layer is deposited on all surfaces of the via at a constant rate. Such deposition may occur through chemical vapor deposition (CVD). In the implementation illustrated by FIG. 1, a seam 8 is left in the middle of the via as the tungsten is deposited to the via from the outside of the shape of the via toward the inside. The seam 8 in the tungsten layer 14 may be inherently created through the use of the conformal deposition process. The dimensions of the seam 8 and its position within the via depend on the geometry of the via (height vs. width, etc.). A surface 12 of the tungsten layer 14, which may be formed through either chemical mechanical polishing or etchback, may include a recess 10 or be recessed relative to the total height of the layer 4 in which the via 2 has been formed.

A method for forming the via illustrated by FIG. 1 may include depositing the liner 6 on a surface 22 of a via formed within layer 4 and a bottom 24 surface of the via. While the liner facilitates adhesion of the tungsten layer 14 to the layer 4 of the semiconductor device, in implementations where the via includes a material aside from tungsten, the method may not include forming a liner within the via.

The method for forming the via illustrated by FIG. 1 includes depositing a tungsten layer 14 over the first liner 6 within the via 2. In various implementation, the tungsten layer 14 may be deposited conformally within the via 2. Such conformal deposition may include depositing the tungsten layer using CVD. Depositing the tungsten layer 14 in this manner results in a seam 8 forming down the middle of the tungsten layer as previously described. In various implementations, depositing the tungsten layer 14 in the via 2 result in the tungsten layer overflowing out of the via and onto the layer 4 of the semiconductor device. In such implementations, the overflowing portion of the tungsten layer is removed through chemical-mechanical polishing (CMP) processes or by tungsten etch back processes. Such processes may exacerbate the unevenness or roughness of the surface 12 of the via as the presence of the seam 8 in the interior of the via results in a greater removal rate of the tungsten layer 14 at that location in the via 2 as compared to the tungsten on the surrounding layer 4 of the semiconductor device. Because of this, the seam may result in a recess 10 or dishing in a part of or in the entire surface 12 of the tungsten layer 14 as illustrated by FIG. 1.

The recess 10 may prove problematic in forming electrical connections to the via 2. Referring to FIG. 2, a cross-section side view photo of three vias similar to the via of FIG. 1 is illustrated. In order to establish a reliable electrical connection, one or more metal layers 16 may be deposited over the vias 18. As illustrated by FIG. 2, after deposition of the one or more metal layers 16, the surface 20 of the one or more metal layers 16 over the via is correspondingly rough and uneven due to the recess, the grain structure, and the seam in the via. Because the surface 20 of the one or more metal layers is uneven, the vias 18 may often be unable to make a reliable contact with the metal layers, thin films, or other types of semiconductor components. Such a situation may result in higher resistance devices or short or long-term device reliability problems.

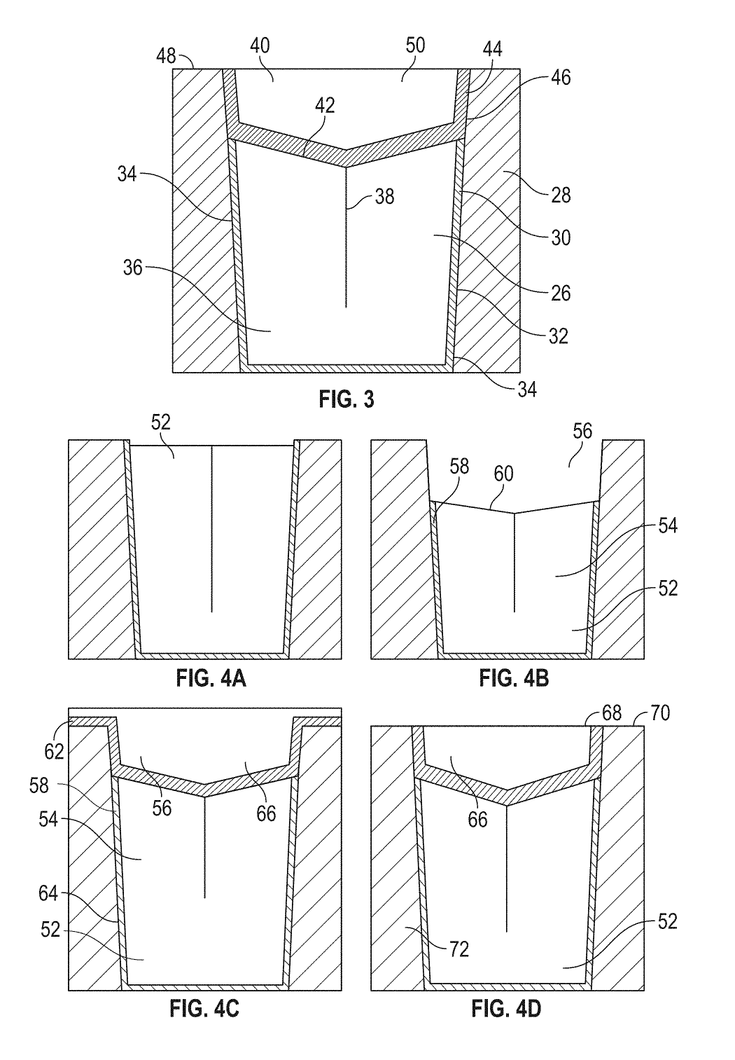

Referring to FIG. 3, a cross-section side view of another implementation of a via is illustrated. As illustrated, the via 26 extends through a layer 28 of a semiconductor device. The layer 28 of the semiconductor device may include, by non-limiting example, an inter-layer dielectric material. In various implementations, the via may include a first liner 30 coupled to a first portion 32 of a surface 34 of the via 26. The first liner 30 may include any metal or metal alloy, and in particular implementations may include, by non-limiting example, titanium, titanium nitride, tantalum, tantalum nitride, or any combination thereof. While the implementation illustrated by FIG. 3 shows the first liner 30 only covering the first portion 32 of the surface 34 of the via 26, in other implementations the first liner may cover the entire surface 34 of the via 26.

As illustrated, the via includes a first tungsten layer 36 deposited conformally within the via. As described previously herein, the first tungsten layer could alternatively be a layer including any other conductive material, including any metal or metal alloy. In implementations where the via 26 includes a first liner 30, the first tungsten layer 36 may be coupled directly to the first liner 30. In implementations where a different conductive material is used in place of tungsten and there is no first liner, the layer of conductive material may be directly coupled to the first portion 32 of the surface 34 of the via 26. The tungsten layer 36 may be deposited using CVD. In the implementation illustrated by FIG. 3, a seam 38 is left in the middle of the via 26 as the tungsten is deposited to the via from the outside of the of the via toward the inside. The seam 38 in the tungsten layer 36 is a result of the conformal deposition process.

In various implementations, the first tungsten layer 36 may be recessed within the via 26. In various implementations, the recess 40 extends into the via 26 less than ½ the width of the via 26. In other implementations, the recess 40 may extend deeper or less deep into the via 26 than ½ the width of the via depending on the geometry of the via. The surface 42 of the first tungsten layer 36 adjacent to the recess may be concave, convex, flat, or any combination thereof.

In various implementations, the via 26 may include a second liner 44 coupled to a second portion 46 of the surface 34 of the via 26 and to the first tungsten layer 36. In various implementations the second liner 44 may be directly coupled to the surface 42 of the first tungsten layer 36 and to the surface 34 of the via 26 formed in layer 28. In various implementations, the second liner 44 may include a material having a higher effective resistance (electrical resistance) than tungsten (or any other alternative material used in place of tungsten). In other implementations, the second liner 44 may include a material having a lower effective resistance than tungsten. In particular implementations, the material of the second liner may include, by non-limiting example, titanium, titanium nitride, tantalum, tantalum nitride, or any combination thereof. The second liner 44 may be of varying thickness. As the second liner has different resistance properties compared to the tungsten layers, the thickness of the second liner may be varied to correspondingly vary the resistance of the via. For example, titanium nitride has a resistance substantially ten times greater than the resistance of tungsten. Thus, by including the second liner it is possible to control the resistance among a plurality of vias all having the same critical dimensions by just changing the thickness and material used for the second liner 44 for those plurality of vias. This runs contrary to other via resistances where it was desirable to keep via resistances the same because the critical dimensions among the vias in a device were typically the same across a die in order to create optimum patterning control and to aid in processing of the vias in other process steps (like CMP). In this way, via resistances can be customized within a silicon die. Also, using these principles, the resistance of an entire set of vias in a layer on a die can be adjusted based on electrical test results to compensate for process variations or produce other desired performance characteristics. In other implementations including a conductive material rather than tungsten for the layer that fills the via 26, the via 26 may not necessarily include a second liner 44.

Still referring to FIG. 3, in various implementations the via 26 may include a second tungsten layer 50 deposited into the recess 40 over the first tungsten layer 36. The second tungsten layer 50 may be directly coupled to the second liner 44. In this manner, the second liner 44 may be between the first tungsten layer 36 and the second tungsten layer 50. In various implementations, a plane formed by the second tungsten layer 50 may be substantially parallel with a plane aligned substantially perpendicularly with a longest dimension of the via 26. Similarly, in various implementations, the second tungsten layer 50 may fill the remainder of the via 26 and, following a polishing process, exhibit a smooth and flat surface substantially coextensive and/or planarized with the top surface 48 of the semiconductor layer 28. The smooth and flat surface may allow for the via to contact, among other things, a thin film, such as various types of SiCr thin films or other metal-containing films. In this way, reliability problems resulting from recessed vias not having strong connections to metal films can be reduced and/or eliminated.

The depth of the second tungsten layer 50 may vary. In various implementations, the depth of the second tungsten layer 50 is less than the half the width of the via 26, though it may be more than half in various implementations. In various implementations the second tungsten layer 50 is a continuous layer of tungsten without any seams therein which is the result of filling an opening with much lower aspect ratios than the original via recess 40.

Referring to FIGS. 4A-4D, a method for forming the via of FIG. 3 is illustrated. Referring specifically to FIG. 4A, the method may include forming a via 52 similar to or the same as via 2 illustrated in FIG. 1 using the methods related to FIG. 1 previously disclosed herein. Referring to FIG. 4B, the method of forming the via of FIG. 3 may include etching a portion of the first tungsten layer 54 to form a recess 56 in the via 52. In particular implementations, the first tungsten layer may be etched using a dry etch selective to tungsten, though in other implementations a wet etch may be employed to form the recess 56 in the first tungsten layer 54. In various implementations, both an upper portion of the first tungsten layer 54 and an upper portion of the first liner 58 may be removed, while in other implementations just the upper portion of the first tungsten layer 54 is removed. In various implementations, substantially half the width of the top surface of the via 52 may be removed, however, in other implementations more or less than this may be removed. The first tungsten layer may be etched to form a concave surface 60, while in other implementations the first tungsten layer is etched to form a flat surface or a convex surface in the surface of the first tungsten layer 54 adjacent to the recess 56.

Referring to FIG. 4C, the method of forming the via of FIG. 3 may include depositing a second liner 62 over the first tungsten layer 54 into the recess 56. The second liner 62 may be any type of liner previously disclosed herein, and may be applied to any surface and in any thickness previously disclosed herein. In other implementations, and as illustrated by FIG. 4C, the second liner 62 may be deposited to the surface 64 of the via 52 and may be deposited using chemical vapor deposition, sputtering, evaporation, or any other deposition process. In implementations where the first liner 58 was not removed during the etch of the first tungsten layer, the second liner may be directly coupled to an upper portion of the first liner. The second liner 62 may facilitate adhesion of a second tungsten material 66 deposited within the via 52 and may also serve as a diffusion barrier.

As illustrated by FIG. 4C, the method of forming the via of FIG. 3 may include depositing a second tungsten layer 66 over the second liner 62 and into the recess 56. The second tungsten layer 66 may be deposited into the recess 56 using CVD in a manner that does not result in a seam therein due to the lower aspect ratio of the via. In various implementations, the second tungsten layer 66 may overfill the via 52 as illustrated in FIG. 4C. In various implementations, the deposition of the second tungsten layer 66 may be limited to avoid excessive overflow of the second tungsten layer onto the surrounding semiconductor layer.

Referring to FIG. 4D, the method of forming the via of FIG. 3 may include removing the overflow portion of the second tungsten layer 66. The overflow portion may be removed through polishing, such as CMP, or through a back etch of the second tungsten layer 66. By removing the overflow portion of the second tungsten layer 66, the surface 68 (or upper surface as oriented in FIG. 4D) of the second tungsten layer 66 is substantially level and smooth. Because of this, the surface 68 may be substantially continuous and level with the surface 70 (or top surface as oriented in FIG. 4D) of the semiconductor layer 72, as is illustrated in FIG. 4D. Similarly, by polishing the second tungsten layer 66, a plane may be formed by the second tungsten layer that may be substantially parallel with a plane aligned substantially perpendicularly with a longest dimension of the via 52 viewed in cross section. The smooth and flat surface may allow for the via 52 to contact, among other things, a thin film, such as various types of SiCr thin films or other metal-containing films.

While this application focuses on forming a flat surface on a tungsten via and being able to vary the effective resistance of the tungsten via, one of ordinary skill in the art would understand that the elements of the vias and related methods disclosed herein may be applied to other vias that do not contain tungsten. As an example, in various implementations, rather than tungsten layers deposited in a via using CVD, copper (or any other metal or conductive material) may be formed in a via using a bottom-up deposition technique (electroplating or electroless plating). In various implementations, the via may be completely filled and then polished using CMP forming a recess. In other implementations, the via may not be completely filled, leaving a recess. A liner, or a seed layer, may then be deposited into the recess. This liner, or seed layer, may have a different effective resistance based on the material and thickness of the liner which works to vary the effective resistance of the via. The remainder of the via may be filled with copper (or any other metal or conductive material) and then CMP polished substantially flat to the top surface of the semiconductor layer.

In other implementations, rather than forming a recess in the via through polishing or etching the conductive material of the via, in implementations where the via is filled using a bottom-up process, the via may only be partially filled initially. A seed layer, or liner, having a varying effective resistance may then be deposited in the via and the remainder of the via may be filled. The top of the via may be polished if needed to ensure a smooth surface. In this manner, essentially any via may be formed with a varying resistance and a smooth surface that allows for reliable electrical connections to various components.

In places where the description above refers to particular implementations of vias and implementing components, sub-components, methods and sub-methods, it should be readily apparent that a number of modifications may be made without departing from the spirit thereof and that these implementations, implementing components, sub-components, methods and sub-methods may be applied to other vias.

What is claimed is:

1. A via for a semiconductor device comprising:
first tungsten layer deposited conformally within the via and recessed within the via; and
a second tungsten layer deposited into the recess over the first tungsten layer;
wherein a plane formed by the second tungsten layer is substantially parallel with a plane aligned substantially perpendicularly with a longest dimension of the via viewed in cross section.

2. The via of claim 1, wherein the second tungsten layer is less than one half a width of the via.

3. The via of claim 1, further comprising a first liner coupled to the first tungsten layer.

4. The via of claim 1, further comprising a second liner coupled between the second tungsten layer and the first tungsten layer.

5. The via of claim 4, wherein the second liner comprises one of TiN and TaN.

6. The via of claim 4, wherein the material of the second liner comprises a higher effective resistance than tungsten.

7. A via for a semiconductor device comprising:
a first liner coupled to a first portion of a surface of the via;
a first layer coupled to the first liner;
a second liner coupled to a second portion of the surface of the via and to the first layer; and
a second layer coupled to the second liner;
wherein a material of second liner has a different effective resistance than a material of the second layer.

8. The via of claim 7, wherein the first layer is tungsten.

9. The via of claim 7, wherein the second layer is tungsten.

10. The via of claim 7, wherein the second layer is deposited into a recess of the first layer.

11. The via of claim 7, wherein the second layer is less than one half a width of the via.

12. The via of claim 7, wherein a plane formed by the second tungsten layer is substantially parallel with a plane aligned substantially perpendicularly with a longest dimension of the via.

13. A method for forming a via comprising:
depositing a first liner on a surface of a via;
depositing a first tungsten layer over the first liner within the via;
polishing the first tungsten layer;
etching a portion of the first tungsten layer to form a recess in the via;
depositing a second liner over the first tungsten layer into the recess;
depositing a second tungsten layer over the second liner into the recess; and
polishing the second tungsten layer.

14. The method of claim 13, wherein the second tungsten layer is deposited using chemical vapor deposition.

15. The method of claim 13, wherein a plane formed by the second tungsten layer is substantially parallel with a plane aligned substantially perpendicularly with a longest dimension of the via.

16. The method of claim 13, wherein the material of the second liner is configured to adjust the effective resistance of the via.

17. The method of claim 13, wherein the second liner comprises one of TiN and TaN.

18. The method of claim 13, wherein the material of the second liner comprises a higher effective resistance than tungsten.

19. The method of claim 13, wherein the second tungsten layer does not comprise a seam therein.
